(19) United States
(12) Patent Application Publication
(10) Pub. No.: US 2024/0417581 A1
(43) Pub. Date: Dec. 19, 2024

(54) TWO-DIMENSIONAL MXENE SURFACE-MODIFIED WITH METAL-ORGANIC NETWORK, METHOD OF PREPARING THE SAME, AND MXENE ORGANIC INK CONTAINING THE SAME

(71) Applicant: KOREA INSTITUTE OF SCIENCE AND TECHNOLOGY, Seoul (KR)

(72) Inventors: Seon Joon KIM, Seoul (KR); Seung Sang HWANG, Seoul (KR); Albert LEE, Seoul (KR); Taegon OH, Seoul (KR); Tae Yun KO, Seoul (KR); Junpyo HONG, Seoul (KR)

(21) Appl. No.: 18/408,448

(22) Filed: Jan. 9, 2024

(30) Foreign Application Priority Data
Jun. 14, 2023 (KR) 10-2023-0076069

(51) Int. Cl. C09D 11/52; C01B 32/907; C09D 11/033; C09D 11/037; H05K 9/00

(52) U.S. Cl. CPC C09D 11/52; C01B 32/907; C09D 11/033; C09D 11/037; H05K 9/0081; C01P 2002/20; C01P 2002/72; C01P 2004/03; C01P 2006/40

(57) ABSTRACT

Disclosed in the present specification are a two-dimensional MXene surface-modified with a metal-organic network, a method of preparing the same, a MXene organic ink containing the same, and uses (e.g., an electromagnetic wave shielding material). In one aspect, the two-dimensional MXene surface-modified with a metal-organic network according to the present invention can use various organic ligands by linking the surface with the organic through the metal, and can be stably dispersed in various organic solvents, especially in industrial non-polar organic solvents as well as polar organic solvents, thereby being applied to a more general-purpose technologies, and securing stability against chemical oxidation to improve long-term stability.

### CROSS REFERENCE TO RELATED APPLICATION

The present application claims priority to Korean Patent Application No. 10-2023-0076069, filed on Jun. 14, 2023, the entire contents of which is incorporated herein for all purposes by this reference.

### BACKGROUND OF THE INVENTION

### Field of the Invention

The present specification relates to a two-dimensional MXene surface-modified with a metal-organic network, a method of preparing the same, a MXene organic ink containing the same, and uses (e.g., an electromagnetic wave shielding material).

### Description of Government-Sponsored Research

This study was supported by the Personal Basic Research Project of the Ministry of Science and ICT (Development of platform-type chemical sensor materials based on two-dimensional MXene nanocomposites, Project No. 1711164354) and the Research operation cost support (R&D) business of the Ministry of Science and ICT (Development of high-frequency/high-power electromagnetic wave solution material component technology for securing future mobility operation reliability, Project No. 1711175402) under the administration of the Korea Institute of Science and Technology.

### Description of the Related Art

MXene materials are transition metal carbide, transition metal nitride, and transition metal carbonitride, which are nanomaterials with a two-dimensional crystalline structure, and have properties such as excellent electrical conductivity, controllability of surface properties, solution processability, and the like. Therefore, the MXene materials have emerged as potential applications in a wide variety of fields, including flexible electrodes, conductive adhesive/bonding materials, electromagnetic wave shielding, flexible heaters, sensors, energy storage electrodes, light emitting diode displays, and the like.

A MXene, which has high electrical conductivity properties, may be synthesized from a ceramic material commonly referred to as MAX. Specifically, the MAX has a three-component stacked structure consisting of a transition metal represented by M (titanium (Ti), niobium (Nb), vanadium (V), tantalum (Ta), molybdenum (Mo), or chromium (Cr)), and a group 14 element represented by A (aluminum (Al), silicon (Si), or the like), and carbon or nitrogen represented by X. A two-dimensional form of MXene is obtained in which only the transition metal and carbon (or nitrogen) remain by selectively removing only the A component such as aluminum through an etching process using a strong acid such as hydrofluoric acid (HF). Due to a synthesis route in strong acid and aqueous solution, terminal groups such as —OH, ═O, —F, —Cl, etc. are generated on a surface of the MXene, especially the —OH group, which gives the MXene hydrophilic properties. The synthesized MXene has excellent water dispersion properties and may be applied to flexible electrodes, conductive adhesive/bonding materials, electromagnetic wave shielding, flexible heaters, sensors, energy storage electrodes, light-emitting diode displays, etc. using a solution process, thus having an advantage in manufacturing films and coatings with high electrical conductivity.

As described above, the MXene prepared by the chemical etching process has the advantage of easy water dispersion due to the large amount of functional groups such as —OH or ═O (hydroxyl or oxide), —F, —Cl, etc. present on the surface, but the MXene has a characteristic of being vulnerable to oxidation, as the MXene dispersed in the aqueous solution is easily oxidized by the water molecules themselves and dissolved oxygen dissolved in the water, turning into metal oxides and losing electrical conductivity properties. In addition, the MXene, which can only be dispersed in water due to surface hydrophilic properties, has a disadvantage in that it is difficult to form a composite material in a uniform state with organic monomers or organic polymers due to low bonding force with other materials (polymers, organics) that have hydrophobic properties. In addition, there is a need for a MXene organic ink that is stable dispersed in a variety of organic solvents other than water dispersion, especially industry-specific organic solvents, for spray coating, spin coating, and inkjet printing applications, which are film and coating solution processes favorable to the electronics industry.

### SUMMARY OF THE INVENTION

In one aspect, the present invention has been made in an effort to solve the above-mentioned problems, and aims to provide a surface-modified two-dimensional MXene that exhibits excellent dispersibility in polar organic solvents as well as in industry-specific non-polar organic solvents such as MEK, THE, PGME, etc. and has excellent electrical conductivity and solution processability, while improving oxidation stability, by chemically modifying a surface of the two-dimensional MXene with a metal-organic network.

In another aspect, the present invention aims to provide a MXene organic ink that is capable of being applied in various fields, such as an electromagnetic wave shielding material, through combination with a hydrophobic polymer.

To achieve the above-mentioned objects, an embodiment of the present invention provides a two-dimensional MXene surface-modified with a metal-organic network.

In addition, an embodiment of the present invention provides a method of preparing the two-dimensional MXene surface-modified with a metal-organic network, the method may include: (1) preparing a metal-organic dispersion by dispersing a mixture of the metal and the organic material in an organic solvent; (2) preparing a Mxene aqueous solution by dispersing two-dimensional MXene in water; and (3) surface-modifying the two-dimensional MXene into a metal-organic network by mixing and stirring the metal-organic dispersion and the MXene aqueous solution.

In addition, an embodiment of the present invention provides a Mxene organic ink containing the two-dimensional MXene surface-modified with the metal-organic network, in which the two-dimensional MXene is dispersed in an organic solvent.

In one aspect, the two-dimensional MXene surface-modified with a metal-organic network according to the present invention can use various organic ligands by linking the surface with the organic through the metal, and can be stably dispersed in various organic solvents, especially in industrial non-polar organic solvents as well as polar organic solvents, thereby being applied to a more general-purpose technologies, and securing stability against chemical oxidation to improve long-term stability.

In another aspect, the surface-modified two-dimensional MXene according to the present invention and the MXene organic ink containing the same can form a composite with various hydrophobic polymers and can be applied in various fields such as a conductive film, an electromagnetic wave shielding material, etc. due to excellent electrical conductivity and coating properties.

### BRIEF DESCRIPTION OF THE DRAWINGS

FIG. 1 schematically illustrates a surface-modified two-dimensional MXene structure according to an embodiment of the present invention.

FIGS. 2A, 2B, 2C, and 2D illustrate results of confirming dispersibility of surface-modified two-dimensional MXene (FIGS. 2A to 2C) and surface-modified two-dimensional MXene with only an organic (FIG. 2D) in various industrial organic solvents according to an embodiment of the present invention.

FIGS. 3A and 3B illustrate appearances and film formation results of MXene organic inks with surface-modified two-dimensional MXene dispersed in MEK solvent, according to an embodiment of the present invention.

FIG. 4 illustrates an X-ray diffraction (XRD) result of the surface-modified two-dimensional MXene according to an embodiment of the present invention.

FIGS. 5A and 5B illustrate preparation of the Mxene organic ink containing surface-modified two-dimensional Mxene and a Mxene-polymer composite film containing TPU, according to an embodiment of the present invention, and results of confirming physical properties thereof.

FIGS. 6A and 6B illustrate scanning electron microscopy (SEM) images (FIG. 6A) and results of confirming electromagnetic wave shielding properties (FIG. 6B), respectively, of the MXene organic ink containing surface-modified two-dimensional MXene and the MXene-polymer composite containing TPU, according to an embodiment of the present invention.

### DETAILED DESCRIPTION OF THE INVENTION

Hereinafter, the present invention will be described in detail.

In one aspect, the present invention may be directed to a two-dimensional MXene that has been surface-modified with a metal-organic network.

In an embodiment, the metal may be one or more selected from palladium (Pd), iron (Fe), cobalt (Co), rhodium (Rh), gold (Au), silver (Ag), nickel (Ni), and copper (Cu).

In an embodiment, the organic may be an organic ligand including one or more selected from a carbonyl group (—CO), hydroxyl group (—OH), carboxylic acid group (—CO₂H), and sulfonic acid group (—SO₃H) directly or indirectly linked to an aryl group, alkyl group, or heterocyclic compound.

In an embodiment, the organic ligand may include one or more of the compounds represented by Chemical Formulas 1 to 15 below.

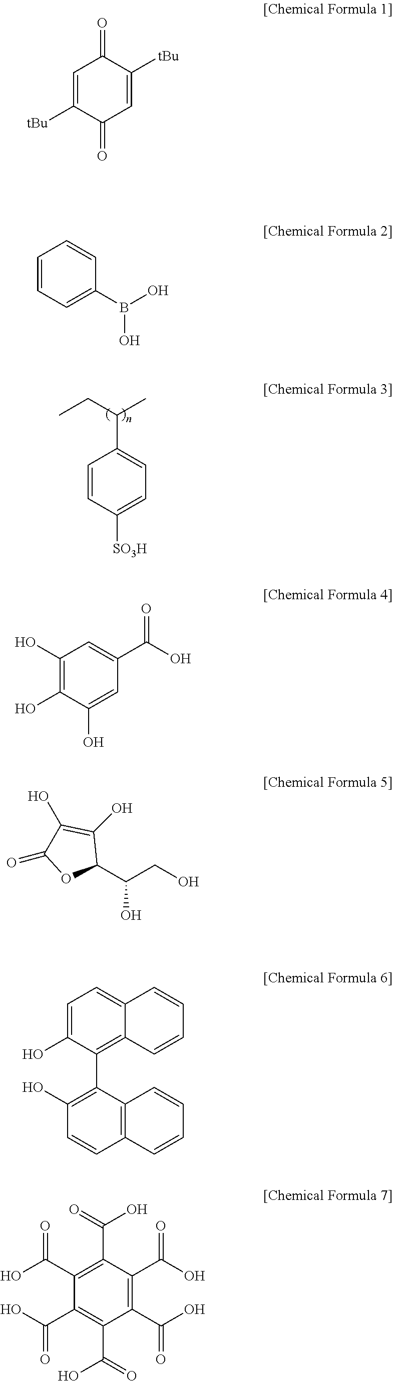

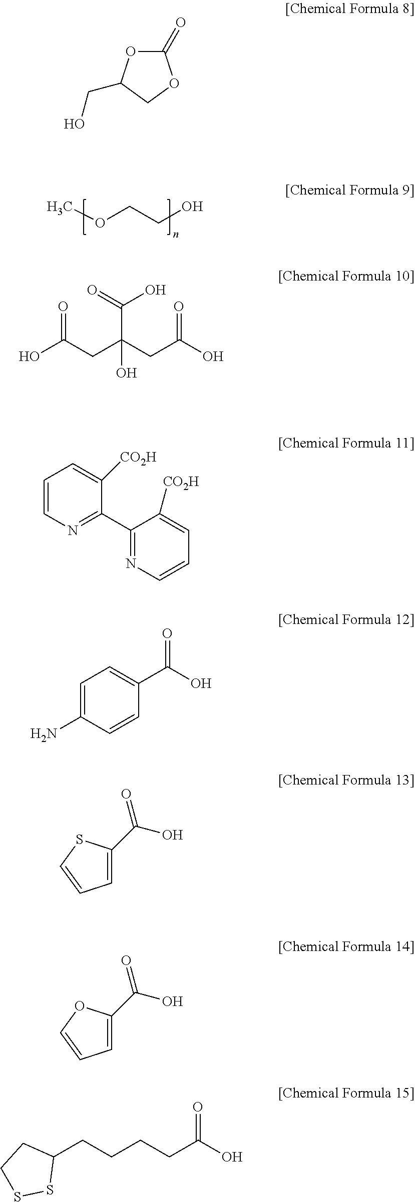

As described above, the two-dimensional MXene according to one aspect of the present invention may be modified with a variety of organic ligands by the metal linking a surface of the MXene to the organic ligand in between.

In an embodiment, the two-dimensional MXene may include at least one or more layers in which crystal cells having an empirical formula of Mₙ₊₁Xₙ form a two-dimensional array.

Here, each X is positioned within an octahedral array formed of a plurality of M, M is at least one metal selected from the group consisting of group IIIB metals, group IVB metals, group VB metals, and group VIB metals, and each X is C, N, or a combination thereof, in which n may be 1, 2, 3, or 4.

In an embodiment, M may be, for example, Sc, Y, Lu, Ti, Zr, Hf, V, Nb, Ta, Cr, Mo, W, or a combination thereof, but is not limited thereto, and the empirical formula of Mₙ₊₁Xₙ may be, for example, Sc₂C, Ti₂C, Ti₃C₂, Nb₂C, V₂C, Ta₄C₃, Mo₂TiC₂, Mo₂ Ti₂C₃, Cr₂TiC₂, Ti₂N, Ti₃CN, Mo₂C, Nb₄C₃, Zr₃C₂, Ti₄N₃, V₄C₃, Hf₃C₂, Mo₂N, Cr₂C, Zr₂C, Nb₂C, Hf₂C, V₃C₂, Ta₃C₂, or Ti₄C₃, but is not limited thereto.

In another embodiment, the two-dimensional MXene may include at least one or more layers in which crystal cells having an empirical formula of M′₂M″ₙXₙ₊₁ form a two-dimensional array.

Here, each X is positioned within an octahedral array formed of a plurality of M′ and M″, M′ and M″ are different metals from each other selected from the group consisting of group IIIB metals, group IVB metals, group VB metals, and group VIB metals, and each X is C, N, or a combination thereof, in which n may be 1 or 2.

In another embodiment, M may be, for example, Ti, V, Nb, Ta, Cr, Mo, or a combination thereof, but is not limited thereto, and the empirical formula of M′₂M″ₙXₙ₊₁ may be, for example, Mo₂VC₂, Mo₂TaC₂, Mo₂NbC₂, Cr₂VC₂, Cr₂TaC₂, Cr₂NbC₂, Ti₂TaC₂, Ti₂NbC₂, V₂TaC₂, V₂TiC₂, Mo₂V₂C₃, Mo₂Nb₂C₃, Mo₂Ta₂C₃, Cr₂Ti₂C₃, Cr₂Ta₂C₃, Cr₂V₂C₃, Cr₂Nb₂C₃, Nb₂Ta₂C₃, Ti₂Nb₂C₃, Ti₂Ta₂C₃, V₂Nb₂C₃, V₂Ta₂C₃, or V₂Ti₂C₃, but is not limited thereto.

In an embodiment, the two-dimensional MXene, which is a target to be surface modified, may be free-standing two-dimensional assemblies with crystalline structures being successively independent, or may be stacked assemblies with the crystalline structures being stacked. In case of the stacked assemblies, atoms, ions, or molecules may be interposed between at least some of the layers, in which case the interposed atoms or ions may be lithium. Accordingly, the surface-modified two-dimensional MXene according to an embodiment of the present invention may also be used in energy storage devices such as a battery or supercapacitor.

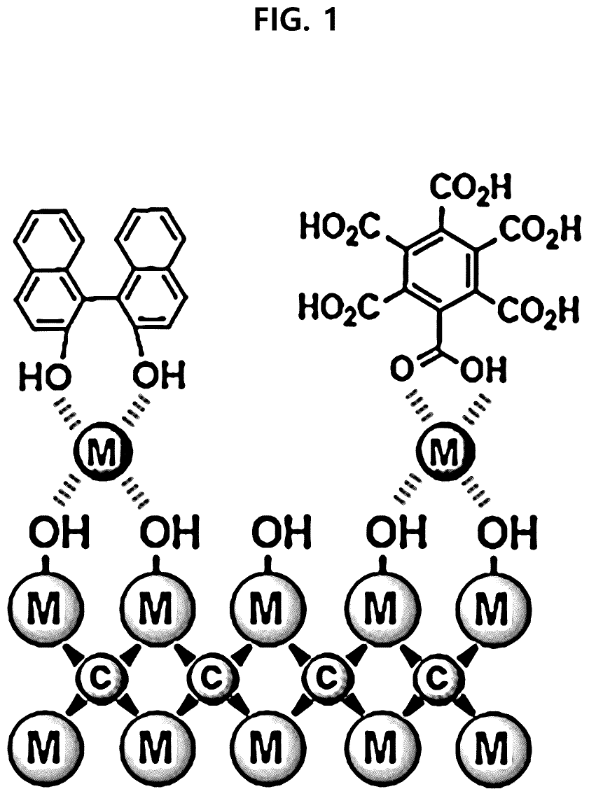

In addition, the surface-modified two-dimensional MXene according to an embodiment of the present invention maintains the crystal structure of the two-dimensional MXene before the surface modification, as illustrated in FIG. 1, and thus retains intrinsic properties of excellent electrical conductivity, magnetic loss, and dielectric loss, and accordingly can be used as conductive flexible electrodes, heaters, or electromagnetic wave shielding and electromagnetic wave absorbing materials.

In another aspect, the present invention may be directed to a method of preparing a two-dimensional MXene surface-modified with a metal-organic network.

In an embodiment, the method of preparing the surface-modified two-dimensional MXene may include step (1) of preparing a metal-organic dispersion by dispersing a mixture of the metal and the organic in an organic solvent; step (2) of preparing a Mxene aqueous solution by dispersing a two-dimensional MXene in water; and step (3) of surface-modifying the two-dimensional MXene into a metal-organic network by mixing and stirring the metal-organic dispersion and the MXene aqueous solution.

Hereinafter, the description of the metal and the organic is omitted since the same is described above.

In an embodiment, the organic solvent may be a C1-C6 lower alcohol.

In an embodiment, the organic solvent may be ethanol.

In an embodiment, the mixture of the metal and the organic may be that the metal and the organic being mixed in a volume ratio of 1:0.1 to 10. Specifically, the volume ratio of the metal to the organic may be 1:0.1 or more, 1:0.5 or more, 1:1 or more, 1:1.1 or more, 1:1.2 or more, 1:1.3 or more, 1:1.4 or more, 1:1.5 or more, 1:1.6 or more, 1:1.7 or more, 1:1.8 or more, 1:1.9 or more, 1:2 or more, 1:2.1 or more, 1:2.2 or more, 1:2.3 or more, 1:2.4 or more, 1:2.5 or more, 1:2.6 or more, 1:2.7 or more, 1:2.8 or more, 1:2.9 or more, 1:3 or more, 1:3.1 or more, 1:3.2 or more, 1:3.3 or more, 1:3.4 or more, 1:3.5 or more, 1:3.6 or more, 1:3.7 or more, 1:3.8 or more, 1:3.9 or more, 1:4 or more, 1:6 or more, or 1:8 or more. In addition, the volume ratio of the metal to the organic may be 1:10 or less, 1:8 or less, 1:6 or less, 1:4 or less, 1:3.9 or less, 1:3.8 or less, 1:3.7 or less, 1:3.6 or less, 1:3.5 or less, 1:3.4 or less, 1:3.3 or less, 1:3.2 or less, 1:3.1 or less, 1:3 or less, 1:2.9 or less, 1:2.8 or less, 1:2.7 or less, 1:2.6 or less, 1:2.5 or less, 1:2.4 or less, 1:2.3 or less, 1:2.2 or less, 1:2.1 or less, 1:2 or less, 1:1.9 or less, 1:1.8 or less, 1:1.7 or less, 1:1.6 or less, 1:1.5 or less, 1:1.4 or less, 1:1.3 or less, 1:1.2 or less, 1:1.1 or less, 1:1 or less, or 1:0.5 or less.

In another aspect, the present invention may be directed to a method of preparing a MXene organic ink containing a two-dimensional MXene surface-modified with a metal-organic network.

In an embodiment, the method of preparing the MXene organic ink containing the surface-modified two-dimensional MXene may further include step (4) of adjusting a concentration of an organic solution, in which the surface-modified two-dimensional MXene is dispersed, or substituting a solvent of the organic solution with a desired organic solvent, where the organic solution is obtained by phase separating the aqueous solution of the two-dimensional MXene prepared through steps (1) to (3) described above and a reactant of the metal-organic dispersion to remove an aqueous solution layer.

In an embodiment, in step (2), the two-dimensional MXene may be dispersed in water through an acid etching process.

In an embodiment, an etchant used in the acid etching process of step (2) described above may be an F-containing strong acid such as HF, NH₄HF₂, or an HCl-LiF mixture, but is not limited thereto. The MXene prepared through the acid etching process described above may be represented by Mₙ₊₁Xₙ(Tₓ) or M′₂M″ₙXₙ₊₁(Tₓ), where Tx is a terminal functional group formed on a surface of the two-dimensional MXene through etching and means —OH, ═O, —F or a combination thereof.

In an embodiment, the organic solvent may be an alkane, olefin, alcohol, aldehyde, amine, ester, ether, ketone, aromatic hydrocarbon, hydrogenated hydrocarbon, terpene olefin, halogenated hydrocarbon, heterocyclic compound, nitrogen-containing compound, sulfur-containing compound, or the like. For example, the organic solvent may be one or more species selected from the group consisting of ethanol, methanol, isopropyl alcohol, n-hexanol, acetone, acetonitrile, dimethyl sulfoxide, dimethylformamide, propylene carbonate, N-methyl-2-pyrrolidone, and tetrahydrofuran, but is not limited thereto, and any organic solvent capable of dispersing the metal-organic network that is the surface modifier of the two-dimensional MXene may be used.

In an embodiment, a stirring speed in step (3) described above may be selected by those skilled in the art to be an appropriate speed depending on conditions such as a volume of the solution, a stirrer, whether a magnetic bar is present, and the stirring may be performed by simply shaking by hand as long as an interfacial reaction may be induced.

In an embodiment, the stirring in step (3) may be performed at a temperature below a boiling point of the organic solvent used. Preferably, the stirring in step (3) may be performed at a temperature of 10 to 40° C. For example, the stirring in step (3) described above may be at 10° C. or more, 11° C. or more, 12° C. or more, 13° C. or more, 14° C. or more, 15° C. or more, 16° C. or more, 17° C. or more, 18° C. or more, 19° C. or more, 20° C. or more, 21° C. or more, 22° C. or more, 23° C. or more, 24° C. or more, 25° C. or more, 26° C. or more, 27° C. or more, 28° C. or more, 29° C. or more, 30° C. or more, 31° C. or more, 32° C. or more, 33° C. or more, 34° C. or more, 35° C. or more, 36° C. or more, 37° C. or more, 38° C. or more, or 39° C. or more. In addition, the stirring in step (3) described above may be performed at a temperature of 40° C. or less, 39° C. or less, 38° C. or less, 37° C. or less, 36° C. or less, 35° C. or less, 34° C. or less, 33° C. or less, 32° C. or less, 31° C. or less, 30° C. or less, 29° C. or less, 28° C. or less, 27° C. or less, 26° C. or less, 25° C. or less, 24° C. or less, 23° C. or less, 22° C. or less, 21° C. or less, 20° C. or less, 19° C. or less, 18° C. or less, 17° C. or less, 16° C. or less, 15° C. or less, 14° C. or less, 13° C. or less, 12° C. or less, or 11° C. or less.

In an embodiment, the stirring in step (3) described above may be performed for 0.5 to 24 hours. For example, the stirring in step (3) above may be performed for 0.5 hours or more, 0.7 hours or more, 0. 9 hours or more, 1 hour or more, 2 hours or more, 4 hours or more, 6 hours or more, 8 hours or more, 10 hours or more, 12 hours or more, 14 hours or more, 16 hours or more, 18 hours or more, 20 hours or more, or 22 hours or more. Further, the stirring in step (3) described above may be performed for 24 hours or less, 22 hours or less, 20 hours or less, 18 hours or less, 16 hours or less, 14 hours or less, 12 hours or less, 10 hours or less, 8 hours or less, 6 hours or less, 4 hours or less, 2 hours or less, 1 hour or less, 0. 9 hours or less, or 0.7 hours or less.

In an embodiment, the concentration of the organic solution in step (4) may be adjusted by concentrating through natural evaporation, rotary vacuum evaporation, centrifugation, or the like, or by diluting through solvent addition, and the substitution of the organic solvent may be performed through centrifugation, sequential concentration and dilution, dialysis, or the like.

In another aspect, the present invention may be directed to a MXene organic ink containing the two-dimensional MXene surface-modified with the metal-organic network, in which the two-dimensional MXene is dispersed in an organic solvent.

In an embodiment, the organic solvent may be an industrial organic solvent.

In an embodiment, the industrial organic solvent may include one or more selected from ethanol, isopropyl alcohol (IPA), acetone, dimethyl sulfoxide (DMSO), dimethylformamide (DMF), N-methyl-2-pyrrolidone (NMP), propylene carbonate, 2-methoxy ethanol (2ME), propylene glycol methyl ether (PGME), tetrahydrofuran (THF), propyleneglycol monomethyl ether (PGME), and methyl ethyl ketone (MEK).

The two-dimensional MXene surface-modified with the metal-organic network or the MXene organic ink prepared as described above has a significantly improved oxidation stability compared to the conventional MXene aqueous solution, which greatly improves long-term storage stability and can be used more efficiently in various solution coating processes such as spray coating, spin coating, and inkjet printing. In particular, the two-dimensional MXene surface-modified with the metal-organic network according to an embodiment of the present invention can be efficiently applied to various fields by stably dispersing not only in polar organic solvents but also in industrial non-polar organic solvents, which are essential for various electrohydro dynamic (EHD) printing, 3D printing businesses, and polymer combination, while having high electrical conductivity. In addition, it is highly favorable for forming a composite with various hydrophobic organic monomer or organic polymer materials, which can be easily applied to the preparation of films and coatings with high electrical conductivity that are applicable to flexible electrodes, conductive adhesive/bonding materials, electromagnetic wave shielding, flexible heaters, sensors, energy storage electrodes, light-emitting diode displays, and the like.

For example, a film formed with a uniform thickness on a substrate can be prepared by evenly applying the MXene organic ink containing the surface-modified two-dimensional MXene according to an embodiment of the present invention to the substrate and evaporating the solvent.

In another embodiment, the MXene organic ink may contain other particles and/or polymers in addition to the surface-modified two-dimensional MXene.

The other particles may include, for example, metals including Ag, Au, Cu, Pd, and Pt; metal oxides including SiO2, ITO, and the like; nitrides; carbides; semiconductors including Si, GaAs, InP, and the like; glasses including silica, boron-based glasses, and the like; liquid crystals such as poly(3,4-ethylenedioxythiophene); organic and inorganic porous materials; organic polymers, and the like, but are not limited thereto.

The polymers may be, for example, epoxy resins, polyvinyl chloride (PVC), polypropylene (PP), polyethylene (PE), polyetherimide (PEI), acrylate-based resins, polyamide (PA), acrylonitrile-butadiene-styrene (ABS), polyamideimide (PAI), polybenzoylimidazole (PBI), polyphenylene sulfide (PPS), polytetrafluoroethylene (PTFE), polyvinylidene fluoride (PVDF), polyethylene terephthalate (PET), polyoxymethylene (POM), polyetherketone (PEK), polyetheretherketone (PEEK), polyaryletherketone (PAEK), liquid crystal polymer (LCP), polyimide (PI), polycarbonate (PC), self-reinforced polyphenylene (SPR), (meth)acrylate-based polymers, urethane (meth) acrylate-based polymers, polystyrene (PS), polyurethane (PU), thermoplastic polyurethane (TPU), and polysiloxanes, but are not limited thereto.

In an embodiment, the MXene organic ink may be the surface-modified two-dimensional MXene dispersed in the organic solvent at a concentration of 0.1 to 100 mg/mL. More specifically, in the MXene organic ink the surface-modified two-dimensional Mxene may be dispersed in the organic solvent at a concentration of 0.1 mg/mL or more, 0.2 mg/mL or more, 0.3 mg/mL or more, 0.4 mg/mL or more, 0.5 mg/mL or more, 0.6 mg/mL or more, 0.7 mg/mL or more, 0.8 mg/mL or more, 0. 9 mg/mL or more, 1 mg/mL or more, 3 mg/mL or more, 5 mg/mL or more, 7 mg/mL or more, 10 mg/mL or more, 15 mg/mL or more, 20 mg/mL or more, 30 mg/mL or more, 40 mg/mL or more, 50 mg/mL or more, 60 mg/mL or more, 70 mg/mL or more, 80 mg/mL or more, or 90 mg/mL or more. In addition, in the MXene organic ink the surface-modified two-dimensional Mxene may be dispersed in the organic solvent at a concentration of 100 mg/mL or less, 90 mg/mL or less, 80 mg/mL or less, 70 mg/mL or less, 60 mg/mL or less, 50 mg/mL or less, 40 mg/mL or less, 30 mg/mL or less, 20 mg/mL or less, 15 mg/mL or less, 10 mg/mL or less, 7 mg/mL or less, 5 mg/mL or less, 3 mg/mL or less, 1 mg/mL or less, 0.9 mg/mL or less, 0.8 mg/mL or less, 0.7 mg/mL or less, 0.6 mg/mL or less, 0.5 mg/mL or less, 0.4 mg/mL or less, 0.3 mg/mL or less, or 0.2 mg/mL or less.

In another aspect, the present invention may be directed to an electrically conductive film including the MXene organic ink.

In an embodiment, the film may be prepared by various solution coating processes such as spray coating, spin coating, inkjet printing, filtration, multilayer coating or dip coating using the MXene organic ink.

In an embodiment, a coating or film including the surface-modified two-dimensional MXene or the MXene organic ink containing the surface-modified two-dimensional MXene has a surface conductivity of at least 1 S/cm or more, and more specifically may have a surface conductivity of at least 100 S/cm, 500 S/cm, 1,000 S/cm, 1,500 S/cm, 2,000 S/cm, 2,500 S/cm, and preferably at least 3,000 S/cm.

In an embodiment, the coating may have a thickness of 1 to 999 nm, for example, the coating may have a thickness of 1 nm or more, 5 nm or more, 10 nm or more, 50 nm or more, 100 nm or more, 150 nm or more, 200 nm or more, 250 nm or more, 300 nm or more, 350 nm or more, 400 nm or more, 450 nm or more, 500 nm or more, 550 nm or more, 600 nm or more, 700 nm or more, or 800 nm or more. In addition, the coating may have a thickness of 999 nm or less, 950 nm or less, 900 nm or less, 800 nm or less, 700 nm or less, 600 nm or less, 550 nm or less, 500 nm or less, 450 nm or less, 400 nm or less, 350 nm or less, 300 nm or less, 250 nm or less, 200 nm or less, 150 nm or less, 100 nm or less, or 50 nm or less.

In an embodiment, the film may have a thickness of 1 to 500 microns (μm), for example, the film may have a thickness of 1 micron or more, 2 microns or more, 3 microns or more, 4 microns or more, 5 microns or more, 6 microns or more, 7 microns or more, 7.5 microns or more, 8 microns or more, 9 microns or more, 10 microns or more, 10.5 microns or more, 11 microns or more, 12 microns or more, 12.5 microns or more, 13 microns or more, 14 microns or more, 15 microns or more, 20 microns or more, 30 microns or more, 40 microns or more, 50 microns or more, 100 microns or more, 150 microns or more, 200 microns or more, 250 microns or more, 300 microns or more, 350 microns or more, 400 microns or more, or 450 microns or more. In addition, the film may have a thickness of 500 microns or less, 470 microns or less, 420 microns or less, 370 microns or less, 320 microns or less, 270 microns or less, 230 microns or less, 170 microns or less, 120 microns or less, 60 microns or less, 50 microns or less, 40 microns or less, 30 microns or less, 20 microns or less, 15 microns or less, 14 microns or less, 13 microns or less, 12 microns or less, 11.5 microns or less, 11 microns or less, 10.5 microns or less, 10 microns or less, 9 microns or less, 8.5 microns or less, 8 microns or less, 7 microns or less, 6 microns or less, 5 microns or less, 4 microns or less, 3 microns or less, or 2 microns or less.

In another aspect, the present invention may be directed to a polymer composite including the MXene organic ink, or a composite for electromagnetic wave shielding.

In an embodiment, the polymer composite may be electrically conductive.

The surface-modified two-dimensional MXene is highly favorable for the formation of composite with various hydrophobic organic monomer or organic polymer materials, and can be applied to flexible electrodes, conductive adhesive/bonding materials, electromagnetic wave shielding, flexible heaters, sensors, energy storage electrodes, and light-emitting diode displays.

In an embodiment, the electrically conductive polymer composite and composite for electromagnetic wave shielding may contain other particles and/or polymers in addition to the MXene organic ink, examples of the other particles and polymers are as described above in detail.

In an embodiment, the electrically conductive polymer composite has a surface conductivity of at least 1 S/cm or more, and more specifically may have a surface conductivity of at least 100 S/cm, 105 S/cm, 110 S/cm, and 115 S/cm, and preferably at least 120 S/cm.

Hereinafter, the content of the present invention will be described in more detail through examples and test examples. However, these examples and test examples are presented for the purpose of understanding the content of the present invention, and the scope of the present invention is not limited to these embodiments and examples, and modifications, substitutions, and insertions known in the art can be made, which are also included in the scope of the present invention.

### <Preparation Example 1>Surface Modification of Two-Dimensional MXene Using Metal-Organic Network and preparation of MXene Organic Ink; Examples 1 to 3 and Comparative Example 1

An aqueous solution of exfoliated MXene (Ti₃C₂Tₓ) (Comparative Example 1), prepared by treating Ti₃AlC₂ powder (average particle diameter≤40 μm) with LiF (Alfa Aesar, 98.5%)-HCl (DAEJUNG, 35 to 37%), was diluted to 1 mg/mL to prepare 30 mL. An ethanol solution of palladium (Pd) (Sigma Aldrich, cas #3375-31-3) and Chemical Formula 6 above (BINOL, Sigma Aldrich, cas #18531-99-2) in a mass ratio of 1:2 was prepared, and a reaction was carried out by mixing the MXene aqueous solution with the Pd-BINOL mixture and stirring for 1 hour at room temperature. After 1 hour, the stirring was stopped and the surface-modified MXene with the Pd-BINOL network (BI-MXene) was separated by centrifugation, and then washed two to three times with an organic solvent that was desired to be substituted (ethanol (etOH), IPA, 2ME, PGME, MeCN, acetone, THE, MEK, DMSO, DMF, NMP, or propylene carbonate (PC)) to prepare a MXene organic ink (Example 1).

In addition, Examples 2 and 3 were prepared in the same manner as Example 1, except that instead of the BINOL of Chemical Formula 6 above, an organic having a sulfonic acid group of Chemical Formula 3 above (poly(4-styrenesulfonic acid) aqueous solution, 18 wt %, molecular weight: about 75,000) and an organic having a carboxylic acid group of Chemical Formula 7 above were used, and Comparative Example 1 was prepared in the same manner as Example 1 above, except that instead of the Pd-BINOL mixture, an organic having a sulfonic acid group of Chemical Formula 3 above (poly(4-styrenesulfonic acid) aqueous solution, 18 wt %, molecular weight: about 75,000) was used.

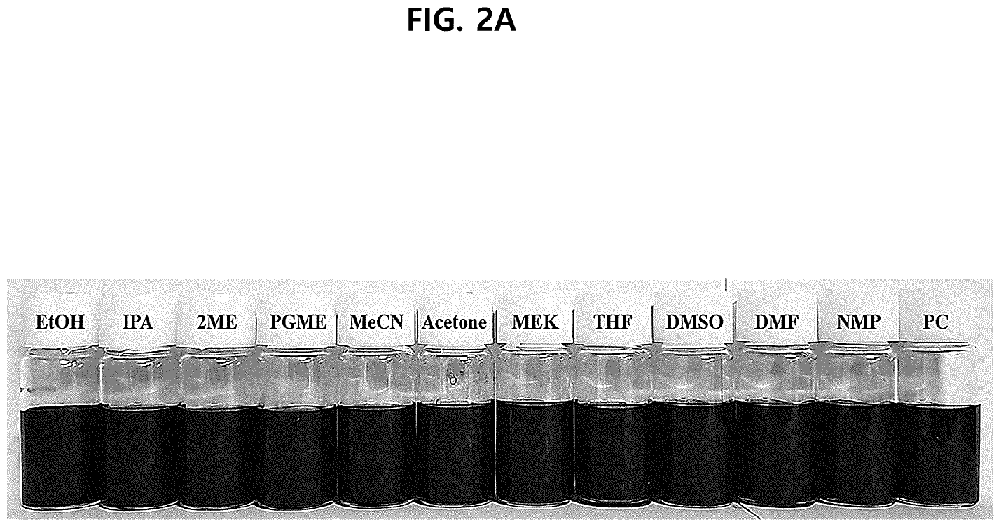

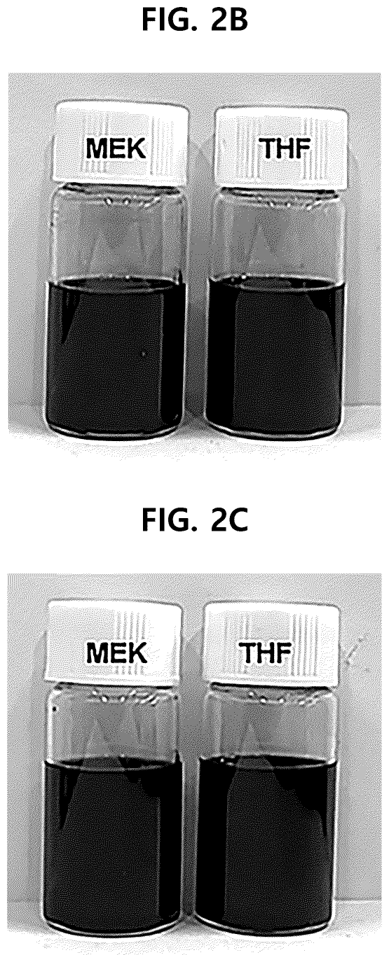

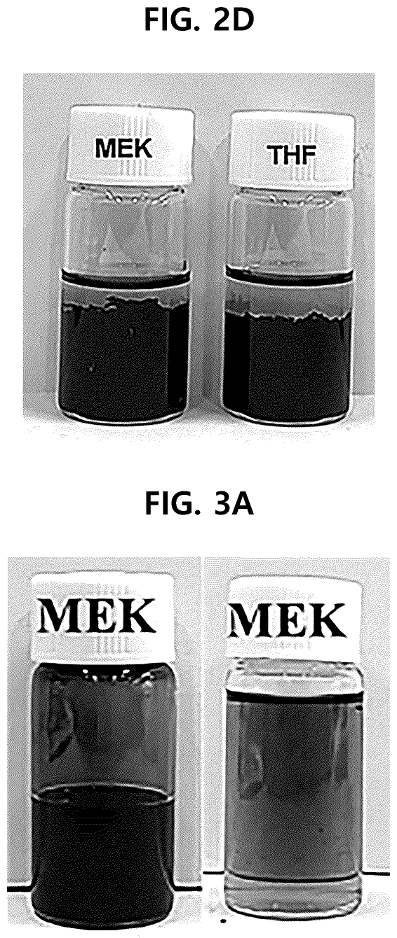

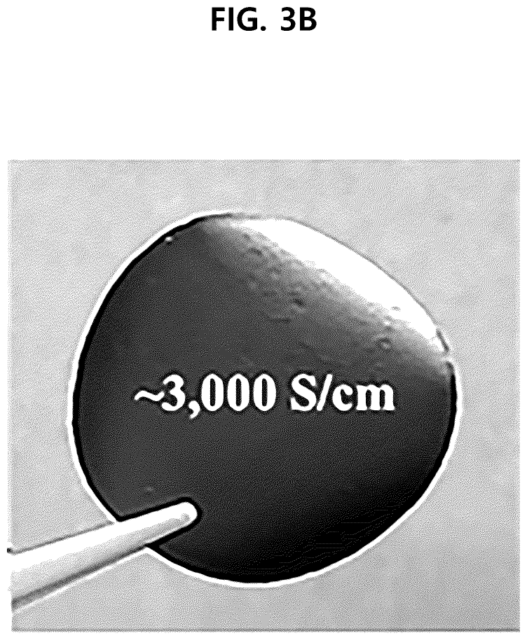

FIG. 2A illustrates appearances of MXene organic inks in which a two-dimensional MXene surface modified with a metal-organic network according to Example 1 above is dispersed in industrial organic solvents (etOH, IPA, 2ME, PGME, MeCN, acetone, THF, MEK, DMSO, DMF, NMP, and PC), respectively, and FIG. 3A illustrates appearances of MXene organic inks dispersed in MEK. In addition, FIGS. 2B and 2C illustrate appearances of MXene organic inks in which the two-dimensional MXene according to Examples 2 and 3 above is dispersed in the industrial organic solvents MEK and THF, respectively, and FIG. 2D illustrates appearances of MXene organic inks in which the two-dimensional MXene surface modified with the organic according to Comparative Example 1 is dispersed in the industrial organic solvents MEK and THF, respectively.

As illustrated in FIGS. 2A to 2C, it was confirmed that the two-dimensional MXenes surface-modified with metal-organic networks according to Examples 1 to 3 were stably dispersed in various industrial organic solvents. In contrast, as illustrated in FIG. 2D, the two-dimensional MXene of the comparative example, which was surface-modified only with an organic without using a metal-organic network, was not dispersed in MEK and THE, and therefore it was confirmed that it was not possible to be filmable, and it was difficult to confirm properties such as electrical conductivity and electromagnetic wave shielding.

In addition, as illustrated in FIG. 3A, it was confirmed that a typical greenish solution appeared when the well-dispersed MXene was prepared at a dilute concentration was observed when two-dimensional MXene surface-modified with a metal-organic network is dispersed in MEK.

### <Test Example 1> Film formation and Electrical Conductivity Measurement of Surface-Modified Two-Dimensional MXene Organic Ink

A film was prepared of a solution of MXene organic ink in which the surface-modified MXene (BI-MXene) prepared in Example 1 above was dispersed in MEK by vacuum filtration using a PVDF separator (pore size: 47 μm). As illustrated in FIG. 3B, the film was well formed, and it was confirmed that electrical conductivity was measured using a 4-pin probe (MCP-TP06P PSP) equipped with a Loresta GP meter (model MCP-T610, MITSUBISHI CHEMICAL), which showed a very high electrical conductivity of 2,870 S/cm.

### <Test Example 2> Interlayer Distance Analysis of Two-Dimensional MXene After Surface Modification Using XRD

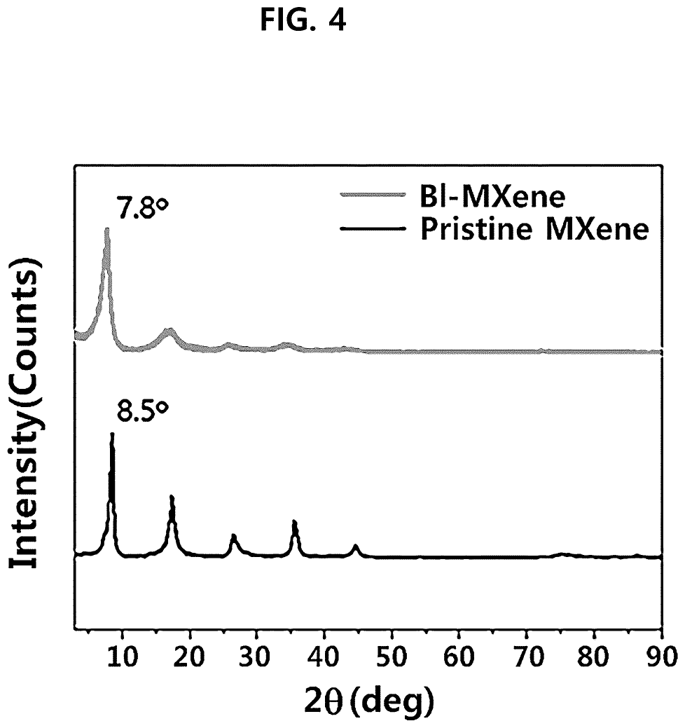

For the MXene surface-modified with Pd-BINOL network (BI-MXene) prepared in Example 1 above, X-ray diffraction (XRD) (D8 Discover, Bruker) was used to analyze the interlayer distance of the two-dimensional MXene after surface modification. The results are shown in FIG. 4.

As illustrated in FIG. 4, it was confirmed that the BINOL compound was successfully modified on the MXene surface through the shift of the (002) peak.

### <Test Example 3> Polymer Composite Composition Using MXene Organic Ink and Film Preparation Using the Same

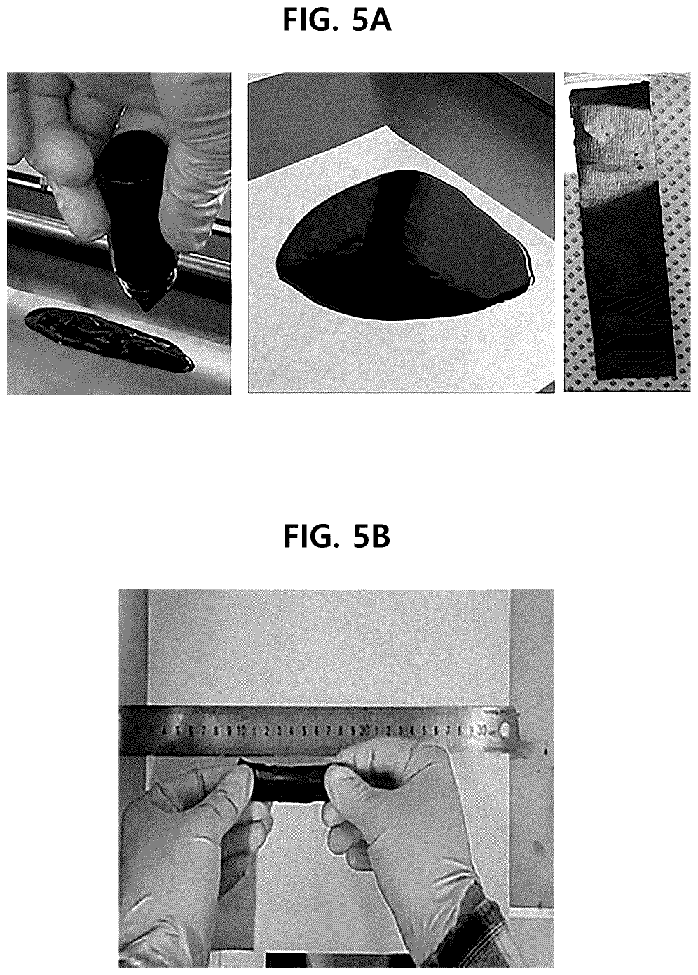

A solution of MXene organic ink (MXene concentration 25% (v/v)) surface modified with Pd-BINOL network and dispersed in MEK according to Example 1 above and a solution of TPU dispersed in MEK at a concentration of 100 mg/mL were mixed in an amount of 45 wt % of the total weight of the solution of MXene organic ink and then stirred with a THINKY centrifugal mixer for 1 minute to obtain a BI-MXene@TPU composite, which was bar-coated to prepare a uniform film. Electrical conductivity of a film prepared by the same method as in Test Example 1 above was measured and showed a high electrical conductivity of 123 S/cm, and an appearance of the prepared film is illustrated in FIGS. 5A and 5B.

As illustrated in FIG. 5A, a uniform film was well formed with a Mxene-polymer composite, and as illustrated in FIG. 5B, it was confirmed that the film maintained properties of TPU.

### <Test Example 4> Structural Analysis and Analysis of Electromagnetic Wave Shielding Properties of MXene Organic Ink-Polymer Composite

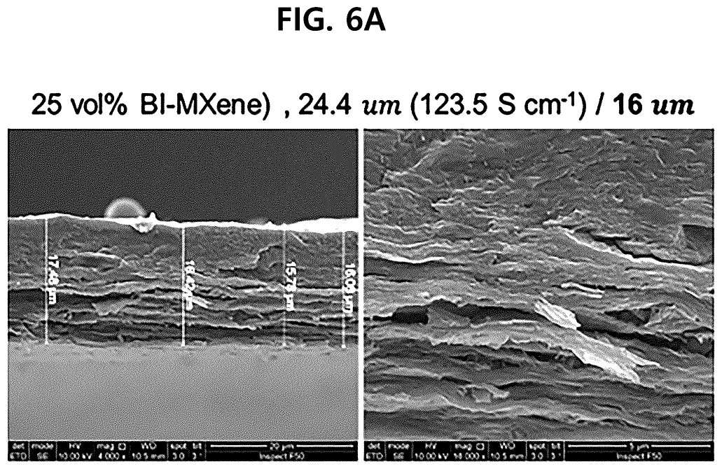

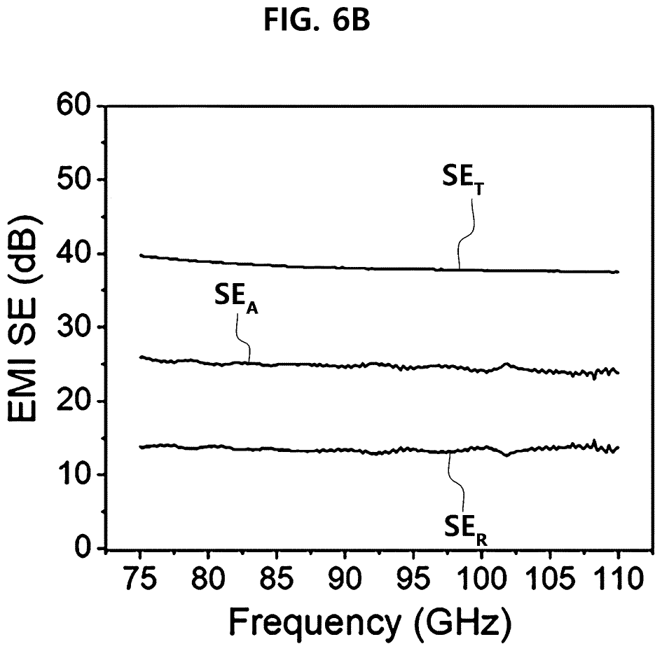

Scanning electron microscopy (SEM) (Hitachi S4700, Hitachi) was used to analyze a stacked structure of the BI-MXene@TPU composite prepared in Example 3 above, and the results are shown in FIG. 6A. As illustrated in FIG. 6A, it was confirmed that the two-dimensional MXene surface-modified with Pb-BINOL, which has good dispersibility in MEK, is uniformly and well mixed with TPU.

In addition, the electromagnetic wave shielding properties of the BI-MXene@TPU composite were analyzed, and the results are shown in FIG. 6B. The electromagnetic wave shielding properties were analyzed by a measurement method using a rectangular-shaped waveguide with a vector network analyzer (VNA, N5222B, Keysight, USA), and the electromagnetic wave shielding properties were confirmed in a frequency band of 8.2 to 110 GHz.

As illustrated in FIG. 6B, it was confirmed that the BI-MXene@TPU composite according to an embodiment of the present invention maintains properties of the TPU polymer (FIG. 5B) while simultaneously having high electromagnetic wave shielding properties of about 40 dB.

What is claimed is:

1. A two-dimensional MXene surface-modified with a metal-organic network.

2. The two-dimensional Mxene of claim 1, wherein the metal is one or more selected from palladium (Pd), iron (Fe), cobalt (Co), rhodium (Rh), gold (Au), silver (Ag), nickel (Ni), and copper (Cu).

3. The two-dimensional Mxene of claim 1, wherein the organic is an organic ligand including one or more selected from a carbonyl group (—CO), hydroxyl group (—OH), carboxylic acid group (—CO₂H), and sulfonic acid group (—SO₃H) directly or indirectly linked to an aryl group, alkyl group, or heterocyclic compound.

4. The two-dimensional Mxene of claim 3, wherein the organic ligand includes one or more of the compounds represented by Chemical Formulas 1 to 15 below:

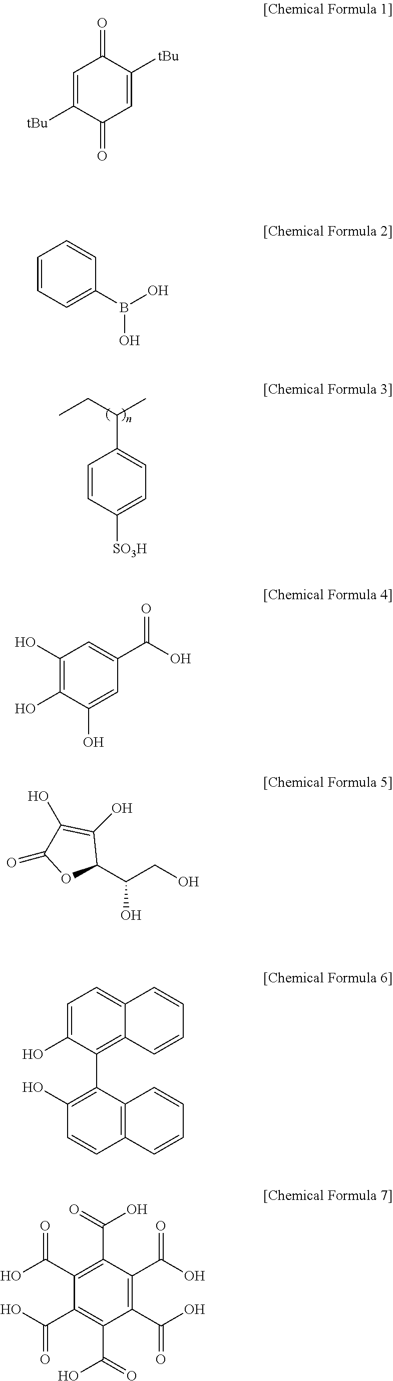

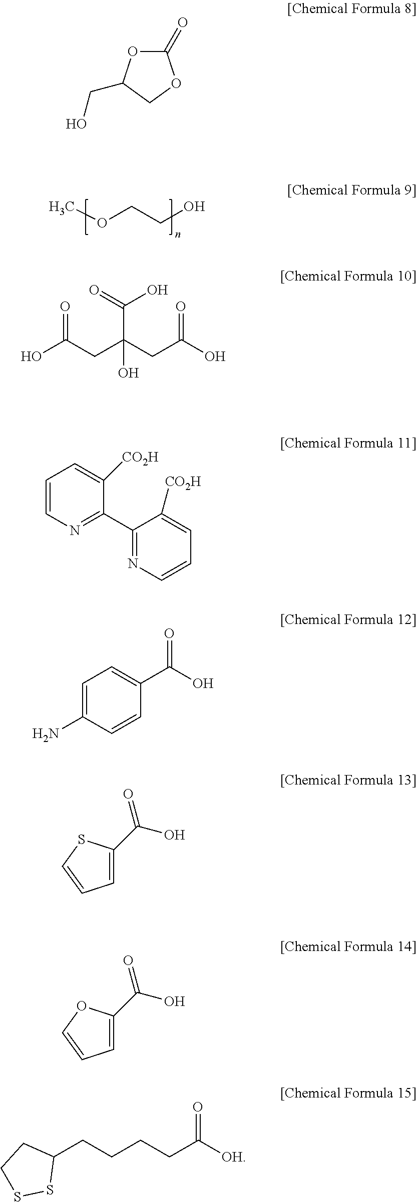

5. The two-dimensional Mxene of claim 1, wherein the two-dimensional MXene, which is a target to be surface-modified, includes at least one or more layers in which crystal cells having an empirical formula of Mₙ₊₁Xₙ form a two-dimensional array, and wherein each X is positioned within an octahedral array formed of a plurality of M, M is at least one metal selected from the group consisting of group IIIB metals, group IVB metals, group VB metals, and group VIB metals, each X is C, N, or a combination thereof, and n is 1, 2, 3, or 4.

6. The two-dimensional Mxene of claim 1, wherein the two-dimensional MXene, which is a target to be surface-modified, includes at least one or more layers in which crystal cells having an empirical formula of M′₂M″ₙXₙ₊₁ form a two-dimensional array, and wherein each X is positioned within an octahedral array formed of a plurality of M′ and M″, M′ and M″ are different metals from each other selected from the group consisting of group IIIB metals, group IVB metals, group VB metals, and group VIB metals, each X is C, N, or a combination thereof, and n is 1 or 2.

7. A method of preparing the two-dimensional MXene surface-modified with a metal-organic network according to claim 1, the method comprising:
(1) preparing a metal-organic dispersion by dispersing a mixture of the metal and the organic in an organic solvent;
(2) preparing a Mxene aqueous solution by dispersing two-dimensional MXene in water; and
(3) surface-modifying the two-dimensional MXene into a metal-organic network by mixing and stirring the metal-organic dispersion and the MXene aqueous solution.

8. The method of claim 7, wherein the mixture of the metal and the organic is that the metal and the organic being mixed in a volume ratio of 1:0.1 to 10.

9. A Mxene organic ink comprising the two-dimensional MXene surface-modified with a metal-organic network according to claim 1, wherein the two-dimensional MXene is dispersed in an organic solvent.

10. The Mxene organic ink of claim 9, wherein the organic solvent is an industrial organic solvent.

11. The Mxene organic ink of claim 10, wherein the industrial organic solvent includes one or more selected from ethanol, isopropyl alcohol (IPA), acetone, dimethyl sulfoxide (DMSO), dimethylformamide (DMF), N-methyl-2-pyrrolidone (NMP), propylene carbonate (PC), 2-methoxy ethanol (2ME), propylene glycol methyl ether (PGME), tetrahydrofuran (THF), propyleneglycol monomethyl ether (PGME), and methyl ethyl ketone (MEK).

12. An electrically conductive film comprising the MXene organic ink according to claim 9.

13. A polymer composite comprising the MXene organic ink according to claim 9.

14. The polymer composite of claim 13, wherein the polymer composite is electrically conductive.
